(19) United States
(12) Patent Application Publication
(10) Pub. No.: US 2015/0118144 A1
(43) Pub. Date: Apr. 30, 2015

(54) DISPERSIBLE METAL CHALCOGENIDE NANOPARTICLES

(71) Applicant: E I DU PONT DE NEMOURS AND COMPANY, Wilmington, DE (US)

(72) Inventors: Yanyan Cao, Wilmington, DE (US); Jonathan V. Caspar, Wilmington, DE (US)

(73) Assignee: E I Du Pont Nemours and Company, Wilmington, DE (US)

(21) Appl. No.: 14/399,537

(22) PCT Filed: Mar. 14, 2013
(86) PCT No.: PCT/US13/31124

§ 371 Date: Nov. 7, 2014

Related U.S. Application Data
(60) Provisional application No. 61/646,405, filed on May 14, 2012.

(51) Int. Cl. C01B 19/00; H01B 13/00; H01L 31/032; C01G 15/00; C09D 11/52; C01G 25/00

(52) U.S. Cl. CPC C01B 19/007; C09D 11/52; C01G 25/006; H01L 31/0322; H01L 31/0326; C01G 15/006; H01B 13/0026
USPC 423/508; 252/519.4; 423/511; 427/126.1

(57) ABSTRACT

The present invention relates to dispersible binary and ternary metal chalcogenide nanoparticle compositions that are substantially free of organic stabilizing agents. These nanoparticle compositions can be used as precursor inks for the preparation of copper zinc tin chalcogenides and copper indium gallium chalcogenides. In addition, this invention provides processes for manufacturing coated substrates and thin films of copper zinc tin chalcogenide and copper indium gallium chalcogenide. This invention also provides process for manufacturing photovoltaic cells incorporating such thin films.

### FIELD OF THE INVENTION

The present invention relates to dispersible binary and ternary metal chalcogenide nanoparticle compositions that are substantially free of organic stabilizing agents. These nanoparticle compositions can be used in precursor inks for the preparation of copper zinc tin chalcogenides and copper indium gallium chalcogenides. In addition, this invention provides processes for manufacturing coated substrates and thin films of copper zinc tin chalcogenide or copper indium gallium chalcogenide. This invention also provides processes for manufacturing photovoltaic cells incorporating such thin films.

### BACKGROUND

Semiconductors such as copper indium gallium sulfide/selenide or CIGS/Se are some of the most promising candidates for thin-film photovoltaic applications. However, due to the limited availability of indium, alternatives are sought. Copper zinc tin sulfide/selenide or CZTS/Se possesses a band gap energy of about 1.5 to 1.0 eV and a large absorption coefficient, making it a promising CIGS/Se replacement. However, current vacuum-based techniques to make CIGS/Se and CZTS/Se thin films (e.g., thermal evaporation, sputtering) require complicated equipment, waste materials by deposition on chamber walls, and tend to be expensive. In contrast, solution-based processes to CIGS/Se and CZTS/Se are less expensive than vacuum-based processes, use less energy, and can utilize close to 100% of the raw materials by precisely and directly depositing materials on a substrate. In addition, solution-based processes are readily adaptable to high-throughput roll-to-roll processing on flexible substrates.

Many of the routes to CIGS/Se and CZTS/Se rely on salt-based precursors (e.g., chlorides, nitrates), which can lead to chlorine- or oxygen-based impurities in the resulting film. Electrochemical deposition is an inexpensive process, but compositional non-uniformity and/or the presence of secondary phases can prevent this method from generating high quality CIGS/Se and CZTS/Se films. The synthesis of CIGS/Se and CZTS/Se films respectively from CIGS and CZTS nanoparticles capped with high-boiling amines, has also been disclosed. The presence of organic capping agents in the nanoparticle layer can contaminate and lower the density of the annealed CZTS/Se film, leading to lower efficiency. Organic-free nanocrystals can be obtained by synthesizing nanoparticles coated with organic stabilizing agents, and then exchanging the organic stabilizing agents with inorganic ligands. However, this can be tedious and expensive.

A molecular precursor approach to CIGS/Se and CZTS/Se involving the preparation of a hydrazine solution or dispersion of metal chalcogenides and elemental chalcogen has been reported. Hydrazine is a highly reactive and potentially explosive solvent that is described in the Merck Index as a “violent poison.”

Processes for synthesizing bulk metal sulfides, selenides, and tellurides include: solid state reactions, e.g., direct combination of the elements in evacuated silica tubes; vapor phase reactions of the metal halides with hydrogen sulfide; and reactions of metal halides with organic sulfur compounds. However, in order to make thin films (1-3 microns), bulk material needs to be processed by milling or other energy intensive processes.

Hence, there still exists a need for routes to CIGS/Se and CZTS/Se that involve simple, low-cost, scalable materials and processes that provide high-quality, crystalline CIGS/Se and CZTS/Se films with tunable composition and morphology. There also exists a need for low-temperature routes to CIGS/Se and CZTS/Se using solvents and reagents with relatively low toxicity and with low potential to contaminate the resulting films.

### SUMMARY OF THE INVENTION

In one aspect, the invention pertains to a process comprising: a) providing a first composition comprising a first solvent and one or more metal complexes, and a second composition comprising a second solvent and a chalcogenide compound selected from the group consisting of sulfides, selenides, and tellurides, wherein the first and second solvents are immiscible; b) combining the first and second compositions to form a third composition; c) agitating the third composition; d) phase-separating the third composition to form a first phase comprising the first solvent and a second phase comprising the second solvent; e) isolating the second phase; and, optionally, f) adding a third solvent to the isolated second phase to form a precipitate and g) isolating the precipitate. The precipitate comprises chalcogenide-capped metal-containing chalcogenide nanoparticles. The nanoparticles, in particular the copper-, zinc-, tin-, indium-, and gallium-containing nanoparticles, are dispersible and can be used in a CZTS/Se and/or CIGS/Se precursor ink.

In another aspect, the invention pertains to a CZTS/Se or CIGS/Se precursor ink comprising chalcogenide-capped metal-containing chalcogenide nanoparticles. In yet another aspect, the invention pertains to i) a process comprising disposing the CZTS/Se or CIGS/Se precursor ink onto a substrate to form a coated substrate and ii) to the coated substrate thus formed.

In one embodiment, the precursor ink is a CZTS/Se precursor ink comprising: a) a fluid medium; b) chalcogenide-capped copper-containing chalcogenide nanoparticles; c) chalcogenide-capped tin-containing chalcogenide nanoparticles; and d) chalcogenide-capped zinc-containing chalcogenide nanoparticles, wherein the molar ratio of total chalcogen to (Cu+Zn+Sn) of the ink is at least about 1, and the molar ratio of Cu:Zn:Sn is about 2:1:1.

In another embodiment, the precursor ink is a CIGS/Se precursor ink comprising: a) a fluid medium; b) chalcogenide-capped copper-containing chalcogenide nanoparticles; c) chalcogenide-capped indium-containing chalcogenide nanoparticles; and, optionally, d) chalcogenide-capped gallium-containing chalcogenide nanoparticles, wherein the molar ratio of total chalcogen to (Cu+In+Ga) of the ink is at least about 1, and the molar ratio of Cu:(In+Ga) is about 1:1.

### DETAILED DESCRIPTION

Herein, the terms “solar cell” and “photovoltaic cell” are synonymous unless specifically defined otherwise. These terms refer to devices that use semiconductors to convert visible and near-visible light energy into usable electrical energy.

As used herein, the term “chalcogen” refers to Group 16 elements, and the term “chalcogenides” refers to materials that comprise Group 16 elements. Suitable Group 16 elements include sulfur, selenium, and tellurium. Herein, the term “binary metal chalcogenide” refers to a chalcogenide composition comprising one metal. The term “ternary metal chalcogenide” refers to a chalcogenide composition comprising two metals. The term “quaternary metal chalcogenide” refers to a chalcogenide composition comprising three metals. The term “multinary metal chalcogenide” refers to a chalcogenide composition comprising two or more metals, and encompasses ternary and quaternary metal chalcogenide compositions.

Herein, the terms “copper tin sulfide” and “CTS” refer to Cu₂SnS₃. “Copper tin selenide” and “CTSe” refer to Cu₂SnSe₃. “Copper tin sulfide/selenide,” “CTS/Se,” and “CTS-Se” encompass all possible combinations of Cu₂Sn(S,Se)₃, including Cu₂SnS₃, Cu₂SnSe₃, and Cu₂SnSₓSe₃₋ₓ, where 0≦x≦3. The terms “copper tin sulfide,” “copper tin selenide,” “copper tin sulfide/selenide,” “CTS,” “CTSe,” “CTS/Se” and “CTS-Se” further encompass fractional stoichiometries, e.g., Cu_{1.80}Sn_{1.05}S₃. That is, the stoichiometry of the elements can vary from a strictly 2:1:3 molar ratio. Similarly, the terms “Cu₂S/Se,” “CuS/Se,” “Cu₄Sn(S/Se)₄,” “Sn(S/Se)₂,” “SnS/Se,” “ZnS/Se”, “In₂(S/Se)₃,” and “Ga₂(S/Se)₃” encompass fractional stoichiometries and all possible combinations of Cu₂(S_{y}Se_{1-y}), Cu(S_{y}Se_{1-y}), Cu₄Sn(S_{y}Se_{1-y})₄, Sn(S_{y}Se_{1-y})₂, Sn(S_{y}Se_{1-y}), Zn(S_{y}Se_{1-y}), “In₂(S_{y}Se_{1-y})₃,” and “Ga₂(S_{y}/Se_{1-y})₃” from 0≦y≦1.

Herein, the term “CZTS” refers to Cu₂ZnSnS₄, “CZTSe” refers to Cu₂ZnSnSe₄, and “CZTS/Se” encompasses all possible combinations of Cu₂ZnSn(S,Se)₄, including Cu₂ZnSnS₄, Cu₂ZnSnSe₄, and Cu₂ZnSnSₓSe₄₋ₓ, where 0≦x≦4. The terms “CZTS,” “CZTSe,” and “CZTS/Se” further encompass copper zinc tin sulfide/selenide semiconductors with fractional stoichiometries, e.g., Cu_{1.94}Zn_{0.63}Sn_{1.3}S₄. That is, the stoichiometry of the elements can vary from strictly 2:1:1:4. Materials designated as CZTS/Se can also contain small amounts of other elements such as sodium. In addition, the Cu, Zn and Sn in CZTS/Se can be partially substituted by other metals. That is, Cu can be partially replaced by Ag and/or Au; Zn by Mn, Fe, Co, Ni, Cd and/or Hg; or Sn by C, Si, Ge and/or Pb.

The ratio of Cu:Zn:Sn in a CZTS/Se precursor ink can differ from the ratio of Cu:Zn:Sn in an annealed film of CZTS/Se derived from a coating of that ink. For example, volatilization of metals or metal chalcogenides can occur during the annealing process.

Herein, the terms “copper indium sulfide” and “CIS” refer to CuInS₂. “Copper indium selenide” and “CISe” refer to CuInSe₂. “Copper indium sulfide/selenide,” “CIS/Se,” and “CIS-Se” encompass all possible combinations of CuIn(S,Se)₂, including CuInS₂, CuInSe₂, and CuInSₓSe₂₋ₓ, where 0≦x≦2.

Herein, the terms “copper indium gallium sulfide/selenide” and “CIGS/Se” and “CIGS-Se” encompass all possible combinations of Cu(In_{y}Ga_{1-y})(SₓSe₂₋ₓ) where O<y≦I and 0≦x≦2. The terms “CIS,” “CISe,” “CIS/Se,” and “CIGS/Se” further encompass copper indium gallium sulfide/selenide semiconductors with fractional stoichiometries, e.g., Cu_{0.7}In_{1.1}S₂. That is, the stoichiometry of the elements can vary from a strictly 1:1:2 molar ratio for Cu:(In+Ga):(S+Se). Materials designated as CIGS/Se can also contain small amounts of other elements such as sodium. In addition, the Cu and In in CIS/Se and CIGS/Se can be partially substituted by other metals. For example, Cu can be partially replaced by Ag and/or Au, or In by B, Al, and/or Tl.

The term “nanoparticle” is meant to include particles characterized by an average longest dimension of about 1 nm to about 1000 nm, or about 5 nm to about 500 nm, or about 10 nm to about 100 nm. Nanoparticles can be in the shape of spheres, rods, wires, tubes, flakes, whiskers, rings, disks, or prisms. Herein, by nanoparticle “size” or “size range” or “size distribution,” we mean that the average longest dimension of a plurality of nanoparticles falls within the specified range. “Longest dimension” is defined herein as the measurement of a nanoparticle from end to end along the major axis of the projection. The “longest dimension” of a particle will depend on the shape of the particle. For example, for particles that are roughly or substantially spherical, the longest dimension will be a diameter of the particle.

As defined herein, “coated particles” refers to particles that have a surface coating of organic or inorganic material. Methods for surface-coating inorganic particles are well-known in the art. As defined herein, the terms “surface coating,” “stabilizing agent,” and “capping agent” are used synonymously and refer to a strongly absorbed or chemically bonded monolayer of organic or inorganic molecules on the surface of the particle(s). Herein, the donor atom of a capping agent refers to the atom within a capping agent that absorbs or chemically bonds to the surface of the particle(s). Suitable inorganic capping agents can comprise chalcogenides, including sulfide, selenide, and telluride capping agents. Herein, the terms “chalcogenide capping agent(s)” encompasses S²⁻, Se²⁻ or Te²⁻ capping agents together with their associated counterions, and nanoparticles coated with these capping agents are termed “chalcogenide-capped nanoparticles”. Herein, all reference to wt % of particles is meant to include any surface coating that may be present.

Herein, by “O-, N-, S-, or Se-based functional groups” is meant univalent groups other than hydrocarbyl and substituted hydrocarbyl that comprise O-, N-, S-, or Se-heteroatoms, wherein the free valence is located on this beteroatom. Examples of O-, N-, S-, or Se-based functional groups include alkoxides, amidos, thiolates, and selenolates.

Herein, the term “metal complexes” refers to compositions wherein a metal is bonded to a surrounding array of molecules or anions, typically called “ligands” or “complexing agents.” The atom within a ligand that is directly bonded to the metal atom or ion is called the “donor atom” and, herein, often comprises nitrogen, oxygen, selenium, or sulfur.

As defined herein, a “hydrocarbyl group” is a univalent group containing only carbon and hydrogen. Examples of hydrocarbyl groups include unsubstituted alkyls, cycloalkyls, and aryl groups, including alkyl-substituted aryl groups. Suitable hydrocarbyl groups and alkyl groups contain 1 to about 30 carbons. By “beteroatom-substituted hydrocarbyl” is meant a hydrocarbyl group that contains one or more heteroatoms wherein the free valence is located on carbon. Suitable beteroatom-substituted hydrocarbyls include O-, N-, S-, Se-, halogen-, or tri(hydrocarbyl)silyl-substituted hydrocarbyls. Examples of beteroatom-substituted hydrocarbyls include hydroxyethyl, carbomethoxyethyl and trifluoromethyl. Herein, the term “tri(hydrocarbyl)silyl” encompasses silyl substituents, wherein the substituents on silicon are hydrocarbyls.

As defined herein, two solvents are “immiscible” if, when these two solvents are combined in some proportions, two phases are produced. In an immisible pair of solvents, the solvents typically differ in polarity. The polarity of solvents can be roughly classified according to dielectric constant. Generally, the lower the dielectric constant, the less polar the solvent. The relative polarity of solvents has also been ranked by a number of classification systems. One of these is the Hansen solubility parameters, which ranks solvents according to three parameters: Delta(D) =dispersion bonds; Delta(P)=polar bonds; and Delta(H)=hydrogen bonds. In immiscible solvent pairs, Delta(P) of the less polar solvent is typically less than 8 on the Hansen scale. Delta(P) of the polar solvent is typically greater than or equal to 8 on the Hansen scale.

One aspect of this invention is a process comprising:

a) providing a first composition comprising a first solvent and a metal complex, and a second composition comprising a second solvent and a compound selected from the group consisting of sulfides, selenides, and tellurides, wherein the first and second solvents are immiscible;
b) combining the first and second compositions to give a third composition and agitating the third composition;
c) allowing the third composition to phase-separate to form a phase comprising the first solvent and a phase comprising the second solvent, and isolating the phase comprising the second solvent.

In some embodiments, the process further comprises:

d) adding a third solvent to the isolated phase comprising the second solvent to form a precipitate; and
e) isolating the precipitate.

Herein, the first solvent is typically an organic-based solvent of lower polarity than the second solvent. In some embodiments, the first solvent has a Delta(P) of less than 8 on the Hansen scale. In some embodiments, the first solvent is selected from the group consisting of: xylene, toluene, pentane, 2-butanone, methyl t-butyl ether, hexane, heptane, ethyl ether, dichloromethane, 1,2-dichloroethane, cyclohexane, chloroform, carbon tetrachloride, butanol, benzene, and mixtures thereof.

Herein, the second solvent is typically water or an organic solvent with a Delta(P) of 8 or higher on the Hansen scale or with a dielectric constant of or 38 or higher. In some embodiments, the second solvent is selected from the group consisting of: water, formamide, dimethylformamide, dimethylsulfoxide, acetic acid, ethanolamine, propylene carbonate, ethylene carbonate, N,N-dimethylacetamide, N-methylformamide and mixtures thereof.

Not all combinations of the first and solvents as listed above are immisible. Suitable combinations of immiscible first and second solvents include: toluene and water; pentane and water; 2-butanone and water; methyl t-butyl ether and water; isooctane and water; hexane and water; heptane and water; ethyl ether and water; ethyl acetate and water; dichloromethane and water; 1,2-dichloroethane and water; cyclohexane and water; chloroform and water; carbon tetrachloride and water; butanol and water; butyl acetate and water; benzene and water; xylene and water; xylene and dimethyl sulfoxide; xylene and dimethylformamide; xylene and formamide; pentane and dimethyl sulfoxide; pentane and dimethylformamide; pentane and formamide; isooctane and dimethyl sulfoxide; isooctane and dimethylformamide; isooctane and formamide; hexane and dimethyl sulfoxide; hexane and dimethylformamide; hexane and formamide; heptane and dimethyl sulfoxide; heptane and dimethylformamide; heptane and formamide; cyclohexane and dimethyl sulfoxide; cyclohexane and dimethylformamide; ethyl ether and dimethyl sulfoxide; pentane and acetic acid; hexane and acetic acid; triethylamine and water; hexane and ethanolamine; heptane and ethanolamine; cyclohexane and ethanolamine; pentane and ethanolamine; ethyl ether and ethanolamine; and diisopropyl ether and water. This list can also be used as a guide to solvent mixtures that are useful as the first or second solvent. For example, a useful first and second solvent combination is hexane and a mixture of dimethyl sulfoxide and ethanolamine.

Suitable third solvents include: acetonitrile, propanediol, methanol, glycol, ethylene glycol and mixtures thereof.

The metal complexes comprise metals selected from the group consisting of Ge, Sn, Pb, Group 3 through Group 13 elements, the lanthanide elements, and the actinide elements. In some embodiments, suitable metals include Mn, Fe, Co, Ni, Cu, Ag, Au, Zn, Cd, Hg, Ga, In, Ge, Sn, and Pb.

Suitable metal complexes include metal complexes of nitrogen-, oxygen-, sulfur- or selenium-based organic ligands. In some embodiments, the organic ligands are selected from the group consisting of: amidos; alkoxides; acetylacetonates; carboxylates; thio- and selenolates; thio-, seleno-, and dithiocarboxylates; dithio-, diseleno-, and thioselenocarbamates; and dithioxanthogenates. Many of these are commercially available or readily synthesized by the addition of an amine, alcohol, or alkyl nucleophile to CS₂ or CSe₂ or CSSe. In some embodiments, suitable nitrogen-, oxygen-, sulfur- or selenium-based organic ligands contain 5 or more carbons; or 8 or more carbons.

Suitable amidos include: bis(trimethylsilyl)amino, dimethylamino, diethylamino, diisopropylamino, N-methyl-t-butylamino, 2-(dimethylamino)-N-methylethylamino, N-methylcyclohexylamino, dicyclohexylamino, N-ethyl-2-methylallylamino, bis(2-methoxyethyl)amino, 2-methylaminomethyl-1,3-dioxolane, pyrrolidino, t-butyl-1-piperazinocarboxylate, N-methylanilino, N-phenylbenzylamino, N-ethyl-o-toluidino, bis(2,2,2-trifluoromethyl)amino, N-t-butyltrimethylsilylamino, and mixtures thereof. Some ligands can chelate the metal center, and, in some cases, comprise more than one type of donor atom, e.g., the dianion of N-benzyl-2-aminoethanol is a suitable ligand comprising both amino and alkoxide groups.

Suitable alkoxides include: methoxide, ethoxide, n-propoxide, i-propoxide, n-butoxide, t-butoxide, neopentoxide, ethylene glycol dialkoxide, 1-methylcyclopentoxide, 2-fluoroethoxide, 2,2,2,-trifluoroethoxide, 2-ethoxyethoxide, 2-methoxyethoxide, 3-methoxy-1-butoxide, methoxyethoxyethoxide, 3,3-diethoxy-1-propoxide, 2-dimethylaminoethoxide, 2-diethylaminoethoxide, 3-dimethylamino-1-propoxide, 3-diethylamino-1-propoxide, 1-dimethylamino-2-propoxide, 1-diethylamino-2-propoxide, 2-(1-pyrrolidinyl)ethoxide, 1-ethyl-3-pyrrolidinoxide, 3-acetyl-1-propoxide, 4-methoxyphenoxide, 4-chlorophenoxide, 4-t-butylphenoxide, 4-cyclopentylphenoxide, 4-ethylphenoxide, 3,5-bis(trifluoromethyl)phenoxide, 3-chloro-5-ethoxyphenoxide, 3,5-dimethoxyphenoxide, 2,4,6-trimethylphenoxide, 3,4,5-trimethylphenoxide, 3,4,5-trimethoxyphenoxide, 4-t-butyl-catecholate(2-), 4-propanoylphenoxide, 4-(ethoxycarbonyl)phenoxide, 3-(methylthio)-1-propoxide, 2-(ethylthio)-1-ethoxide, 2-(methylthio)ethoxide, 4-(methylthio)-1-butoxide, 3-(methylthio)-1-hexoxide, 2-methoxybenzylalkoxide, 2-(trimethylsilyl)ethoxide, (trimethylsilyl)methoxide, 1-(trimethylsily)ethoxide, 3-(trimethylsilyl)propoxide, 3-methylthio-1-propoxide, and mixtures thereof.

Herein, the term acetylacetonate refers to the anion of 1,3-dicarbonyl compounds, A¹C(O)CH(A²)C(O)A¹, wherein each A¹ is independently selected from hydrocarbyl, substituted hydrocarbyl, and O-, S-, and N-based functional groups and each A² is independently selected from hydrocarbyl, substituted hydrocarbyl, halogen, and O-, S-, and N-based functional groups. Suitable acetylacetonates include: 2,4-pentanedionate, 3-methyl-2-4-pentanedionate, 3-ethyl-2,4-pentanedionate, 3-chloro-2,4-pentanedionate, 1,1,1-trifluoro-2,4-pentanedionate, 1,1,1,5,5,5-hexafluoro-2,4-pentanedionate, 1,1,1,5,5,6,6,6-octafluoro-2,4-hexanedionate, ethyl 4,4,4-trifluoroacetoacetate, 2-methoxyethylacetoacetate, methylacetoacetate, ethylacetoacetate, t-butylacetoacetate, 1-phenyl-1,3-butanedionate, 2,2,6,6-tetramethyl-3,5-heptanedionate, allyloxyethoxytrifluoroacetoacetate, 4,4,4-trifluoro-1-phenyl-1,3-butanedionate, 1,3-diphenyl-1,3-propanedionate, 6,6,7,7,8,8,8-heptafluoro-2-2-dimethyl-3,5-octanedionate, and mixtures thereof.

Suitable carboxylates include: acetate, trifluoroacetate, propionate, butyrates, hexanoate, octanoate, decanoate, stearate, isobutyrate, t-butylacetate, heptafluorobutyrate, methoxyacetate, ethoxyacetate, methoxypropionate, 2-ethylhexanoate, 2-(2-methoxyethoxy)acetate, 2-[2-(2-methoxyethoxy)ethoxy]acetate, (methylthio)acetate, tetrahydro-2-furoate, 4-acetylbutyrate, phenylacetate, 3-methoxyphenylacetate, (trimethylsilyl)acetate, 3-(trimethylsilyl)propionate, maleate, benzoate, acetylenedicarboxylate, and mixtures thereof.

Thio- and Selenolates. Suitable thio- and selenolates include: 1-thioglycerol, phenylthio, ethylthio, methylthio, n-propylthio, i-propylthio, n-butylthio, i-butylthio, t-butylthio, n-pentylthio, n-hexylthio, n-heptylthio, n-octylthio, n-nonylthio, n-decylthio, n-dodecyithio, 2-methoxyethylthio, 2-ethoxyethylthio, 1,2-ethanedithiolate, 2-pyridinethiolate, 3,5-bis(trifluoromethyl)benzenethiolate, toluene-3,4-dithiolate, 1,2-benzenedithiolate, 2-dimethylaminoethanethialate, 2-diethylaminoethanethiolate, 2-propene-1-thiolate, 2-hydroxythiolate, 3-hydroxythiolate, methyl-3-mercaptopropionate anion, cyclopentanethiolate, 2-(2-methoxyethoxy)ethanethiolate, 2-(trimethylsilyl)ethanethiolate, pentafluorophenylthiolate, 3,5-dichlorobenzenethiolate, phenylthiolate, cyclohexanethiolate, 4-chlorobenzenemethanethiolate, 4-fluorobenzenemethanethiolate, 2-methoxybenzenethiolate, 4-methoxybenzenethiolate, benzylthiolate, 3-methylbenzylthialate, 3-ethoxybenzenethiolate, 2,5-dimethoxybenzenethiolate, 2-phenylethanethiolate, 4-t-butylbenzenethiolate, 4-t-butylbenzylthiolate, phenylselenolate, methylselenolate, ethylselenolate, n-propylselenolate, i-propylselenolate, n-butylselenolate, i-butylselenolate, t-butylselenolate, pentylselenolate, hexylselenolate, octylselenolate, benzylselenolate, and mixtures thereof.

Suitable thio-, seleno-, and dithiocarboxylates include: thioacetate, thiobenzoate, selenobenzoate, dithiobenzoate, and mixtures thereof. Suitable dithio-, diseleno-, and thioselenocarbamates include: dimethyldithiocarbamate, diethyldithiocarbamate, dipropyldithiocarbamate, dibutyldithiocarbamate, bis(hydroxyethyl)dithiocarbamate, dibenzyldithiocarbamate, dimethyldiselenocarbamate, diethyldiselenocarbamate, dipropyldiselenocarbamate, dibutyldiselenocarbamate, dibenzyldiselenocarbamate, and mixtures thereof. Suitable dithioxanthogenates include: methylxanthogenate, ethylxanthogenate, i-propylxanthogenate, and mixtures thereof.

Suitable sulfides, selenides, and tellurides for use in the synthesis of binary and ternary chalcogenide nanoparticles include Group 1 sulfides, selenides, and tellurides; Group 2 sulfides, selenides, and tellurides, and ammonium sulfides, selenides and tellerides. In some embodiments, suitable sulfides, selenides, and tellurides are selected from the group consisting of Li₂S, Li₂Se, Li₂Te, Na₂S, Na₂Se, Na₂Te, K₂S, K₂Se, K₂Te, MgS, MgSe, MgTe, CaS, CaSe, CaTe, (NHₘR¹₄₋ₘ)₂S, (NHₘR¹₄₋ₘ)₂Se, (NHₘR¹₄₋ₘ)₂Te, and mixtures thereof, wherein 0≦m≦4 and wherein each R¹ is independently selected from the group consisting of hydrogen, hydrocarbyl, and O-, N-, S- Se-, halogen- or tri(hydrocarbyl)silyl-substituted hydrocarbyl. In some embodiments, suitable sulfides, selenides, and tellurides comprise (NH₄)₂S, (NH₄)₂Se, or (NH₄)₂Te. In some embodiments, suitable sulfides, selenides, and tellurides comprise a mixture of Na₂(S,Se,Te) and (NH₄)₂(S,Se,Te), wherein the ratio of Na to [Na+(NH₄)] is less than 0.5 or 0.3 or 0.2 or 0.1, and wherein Na₂(S,Se,Te) and (NH₄)₂(S,Se,Te) independently encompass all possible combinations of Na₂(SᵣSeₛTeₜ) and (NH₄)₂(SᵣSeₛTeₜ) where 0≦r≦1, 0≦s≦1 0≦t≦1, and r+s+t=1.

Typically, the first composition comprises 0.001-2 mol/L of the metal complex. Typically, the second composition comprises 0.1-48 wt % of the sulfides, selenides, and/or tellurides.

Combining the first and second compositions (as described in step b of the process) can be carried out by simply pouring one composition into the other. The combined compositions do not form a homogeneous mixture, and the reaction of the metal complex and the sulfide, selenide and/or telluride is facilitated by vigorous agitation (e.g., stirring or shaking) for periods of less than 1 sec to a few tens of minutes depending on how vigorous the agitation is.

Next, the combined composition is allowed to phase-separate, and the phase comprising the second solvent is isolated. In some embodiments, addition of a third solvent to the isolated second phase precipitates the desired metal chalcogenide as chalcogenide-capped nanoparticles, which can be isolated by centrifugation or filtration. The isolated nanoparticles can optionally be washed with a solvent.

Another aspect of the invention is a CZTS/Se precursor ink comprising:

a) a fluid medium;
b) chalcogenide-capped copper-containing chalcogenide nanoparticles;
c) chalcogenide-capped tin-containing chalcogenide nanoparticles; and
d) chalcogenide-capped zinc-containing chalcogenide nanoparticles,
wherein:
the molar ratio of total chalcogen to (Cu+Zn+Sn) of the ink is at least about 1; and the molar ratio of Cu:Zn:Sn is about 2:1:1.

Another aspect of the invention is a CIGS/Se precursor ink comprising:

a) a fluid medium;
b) chalcogenide-capped copper-containing chalcogenide nanoparticles;
c) chalcogenide-capped indium-containing chalcogenide nanoparticles;
and, optionally,
d) chalcogenide-capped gallium-containing chalcogenide nanoparticles,
wherein:
the molar ratio of total chalcogen to (Cu+In+Ga) of the ink is at least about 1; and
the molar ratio of Cu:(In+Ga) is about 1:1.

In some embodiments, the precursor ink consists essentially of components (a)-(d). In some embodiments, the ink comprises an elemental chalcogen selected from the group consisting of sulfur, selenium, and mixtures thereof. In some embodiments, the at least one layer of the coated substrate consists essentially of components (i)-(iii). In some embodiments, the at least one layer comprises an elemental chalcogen selected from the group consisting of sulfur, selenium, and mixtures thereof.

In some embodiments, the copper-containing chalcogenide is selected from the group consisting of Cu₂S, CuS, Cu₂Se, CuSe, Cu₂(S,Se), Cu(S,Se), Cu₂SnS₃, Cu₄SnS₄, Cu₂SnSe₃, Cu₂Sn(S,Se)₃, and mixtures thereof. In some embodiments, the tin-containing chalcogenide is selected from the group consisting of SnS₂, SnS, SnSe₂, SnSe, Sn(S,Se)₂, Sn(S,Se), Cu₂SnS₃, Cu₄SnS₄, Cu₂SnSe₃, Cu₂Sn(S,Se)₃, and mixtures thereof. In some embodiments, the zinc-containing chalcogenide is selected from the group consisting of ZnS, ZnSe, Zn(S,Se), and mixtures thereof. In some embodiments, the copper-, tin-, and zinc-containing chalcogenides comprise: (a) CuS, SnS, and ZnS; (b) Cu₂SnS₃ and ZnS; (c) Cu₂SnS₃, ZnS, and SnS; or (d) Cu₂SnS₃, CuS, ZnS, and SnS. In some embodiments, the copper-, tin-, and zinc-containing chalcogenides consist essentially of: (a) CuS, SnS, and ZnS; (b) Cu₂SnS₃ and ZnS; (c) Cu₂SnS₃, ZnS, and SnS; or (d) Cu₂SnS₃, CuS, ZnS, and SnS.

In some embodiments, the indium-containing chalcogenide is selected from the group consisting of In₂S₃, In₂Se₃, In₂(S,Se)₃, and mixtures thereof. In some embodiments, the gallium-containing chalcogenide is selected from the group consisting of Ga₂S₃, Ga₂Se₃, Ga₂(S,Se)₃, and mixtures thereof.

Precursor inks of the chalcogenide-capped nanoparticles can be prepared by dispersing the nanoparticles in a fluid medium. The dispersion of the chalcogenide-capped nanoparticles in the fluid medium can be aided by agitation or sonication. In some embodiments, the CZTS/Se or CIGS/Se precursor ink is prepared by dispersing in a fluid medium a mixture comprising the chalcogenide-capped nanoparticles of each metal component. In some embodiments, the chalcogenide-capped nanoparticles of each metal component are separately dispersed in fluid media, and the resulting dispersions are then mixed. In some embodiments, the preparation is conducted under an inert atmosphere.

In some embodiments, the CZTS/Se precursor ink comprises chalcogenide-capped Cu₂SnS/Se₃ and chalcogenide-capped ZnS/Se nanoparticles in about a 1:1 molar ratio. In some embodiments, the CZTS/Se precursor ink comprises chalcogenide-capped CuS/Se, chalcogenide-capped ZnS/Se and chalcogenide-capped SnS/Se nanoparticles in about a 2:1:1 molar ratio.

In some embodiments, the CIGS/Se precursor ink comprises chalcogenide-capped CuS/Se nanoparticles and chalcogenide-capped In₂(S,Se)₃ nanoparticles. In some embodiments the CIGS/Se precursor ink further comprises chalcogenide-capped Ga₂(S,Se)₃ nanoparticles.

In some embodiments, the ratio of S:[S+Se] in the chalgenide-capped nanoparticles of the CZTS/Se and CIGS/Se precursor inks is 1 or about 0.9, 0.8, 0.7, 0.6, 0.5, 0.4, 0.3, 0.2, 0.1, or 0.

In some embodiments, two or more CZTS/Se precursor inks or two or more CIGS/Se precursors inks are prepared separately and then combined. This method is especially useful for controlling stoichiometry and obtaining CZTS/Se or CIGS/Se of high purity, as prior to mixing, separate films from each precursor ink can be coated, annealed, and analyzed by XRD. The XRD results can guide the selection of the type and amount of each ink to be combined. For example, a precursor ink yielding an annealed film of CZTS/Se with traces of copper sulfide and zinc sulfide can be combined with a precursor ink yielding an annealed film of CZTS/Se with traces of tin sulfide, to form a precursor ink that yields an annealed film comprising only CZTS/Se, as determined by XRD. In other embodiments, an ink comprising a complete set of reagents is combined with ink(s) comprising a partial set of reagents. For example, an ink containing only a tin source can be added in varying amounts to a CZTS/Se precursor ink comprising a complete set of reagents, and the stoichiometry can be optimized based upon the resulting device performances of annealed films of the mixtures. Suitable tin sources include tin nanoparticles, tin-containing chalcogenide nanoparticles, and tin complexes. Suitable tin complexes include tin complexes of N-, O-, C-, S-, or Se-based organic ligands. In some embodiments, an ink comprising chalcogenide-capped SnS nanoparticles is combined with a precursor ink comprising chalcogenide-capped Cu₂SnS₃ nanoparticles and chalcogenide-capped ZnS nanoparticles. The ink comprises a fluid medium to carry the chalcogenide-capped nanoparticles. The fluid medium typically comprises 30-99 wt %, 50-95 wt %, 60-90 wt %, 50-98 wt %, 60-98 wt %, 70-98 wt %, 75-98 wt %, 80-98 wt %, 85-98 wt %, 75-95 wt %, 80-95 wt %, or 85-95 wt % of the total weight of the ink. The fluid medium is either a fluid at room temperature or a low-melting solid with a melting point of less than about 100° C., 90° C., 80° C., 70° C., 60° C., 50° C., 40° C., or 30° C. In some embodiments, the fluid medium comprises solvents to aid in the dissolution of some ink components. In some embodiments, the solvents have a Delta(P) greater than or equal to 8 on the Hansen scale. In some embodiments, suitable solvents include: heteroaromatics, organic halides; ketones; esters; nitriles; amides; amines; pyrrolidinones; ethers; alcohols; carbonates; water; and mixtures thereof.

Suitable beteroaromatic solvents include: pyridine, 2-methylpyridine, 3-methylpyridine, 4-methylpyridine, 3,5-lutidine, 2,6-lutidine, 4-t-butylpyridine, 2-aminopyridine, 3-aminopyridine, diethylnicotinamide, 3-cyanopyridine, 3-fluoropyridine, 3-chloropyridine, 2,3-dichloropyridine, 2,5-dichloropyridine, 5,6,7,8-tetrahydroisoquinoline, 6-chloro-2-picoline, 2-methoxypyridine, 3-(aminomethyl)pyridine, 2-amino-3-picoline, 2-amino-6-picoline, 2-amino-2-chloropyridine, 2,3-diaminopyridine, 3,4-diaminopyridine, 2-methylamino)pyridine, 2-dimethylaminopyridine, 2-(aminomethyl)pyridine, 2-(2-aminoethyl)pyridine, 2-methoxypyridine, 2-butoxypyridine, pyrrole, quinoline, and mixtures thereof.

Suitable organic halides include chloroform, dichloromethane, 1,2-dichloroethane, 1,1,1-trichloroethane, 1,1,2-trichloroethane, 1,1,2,2-tetrachloroethane, and mixtures thereof.

Suitable ketones include acetone, 2-butanone, 2-pentanone, 2-hexanone, 4-methyl-2-pentanone, 2-heptanone, 3-heptanone, 5-methyl-3-heptanone, 4-heptanone, methyl isoamyl ketone, 2-octanone, 5-methyl-2-octanone, diisobutyl ketone, cyclopentanone, cyclohexanone, methylcyclohexanone, 2,5-hexanedione, fenchone, acetophenone, and mixtures thereof.

Suitable esters include ethyl formate, propyl formate, butyl formate, amyl formate, hexyl formate, methyl acetate, ethyl acetate, n-propyl acetate, isopropyl acetate, n-butylacetate, sec-butylacetate, isobutylacetate, amyl acetate, sec-amyl acetate, pentacetate, methyl amyl acetate, 2-ethyl butyl acetate, 2-ethylhexylacetate, cyclohexylacetate, methylcyclohexanyl acetate, ethylene glycol monoacetate, ethylene glycol diacetate, ethylene glycol monomethyl ether acetate, ethylene glycol monoethyl ether acetate, ethylene glycol monobutyl ether acetate, diethylene glycol monoethyl ether acetate, diethylene glycol monobutyl ether acetate, propylene glycol monomethyl ether acetate, dipropylene glycol monomethyl ether acetate, methyl propionate, ethyl propionate, n-butyl propionate, amyl propionate, ethyl 3-ethoxypropionate, methyl butyrate, ethyl butyrate, n-butyl butyrate, ethyl oxybutyrate, isobutyl isobutyrate, 2,2,4-trimethylpentanediol-1,3-monoisobutyrate, 1-methoxy-2-propanol acetate, ethoxy propanol acetate, dimethyl succinate, dimethyl adipate, dimethyl glutarate, gamma-butyrolactone, diethyl oxalate, dibutyl oxalate, methyl lactate, ethyl lactate, propyl lactate, butyl lactate, amyl lactate, and mixtures thereof.

Suitable nitrile solvents include: acetonitrile, 3-ethoxypropionitrile, 2,2-diethoxypropionitrile, 3,3-diethoxypropionitrile, diethoxyacetonitrile, 3,3-dimethoxypropionitrile, 3-cyanopropionaldehyde dimethylacetal, dimethylcyanamide, diethylcyanamide, diisopropylcyanamide, 1-pyrrolidinecarbonitrile, 1-piperidinecarbonitrile, 4-morpholinecarbonitrile, methylaminoacetonitrile, butylaminoacetonitrile, dimethylaminoacetonitrile, diethylaminoacetonitrile, N-methyl-beta-alaninenitrile, 3,3′-iminopropionitrile, 3-(dimethylamino)propionitrile, 1-piperidinepropionitrile, 1-pyrrolidinebutyronitrile, propionitrile, butyronitrile, valeronitrile, isovaleronitrile, 3-methoxypropionitrile, 3-cyanopyridine, 4-amino-2-chlorobenzonitrile, 4-acetylbenzonitrile, and mixtures thereof.

Suitable amide solvents include: N,N-diethylnicotinamide, N-methylnicotinamide, formamide, N,N-dimethylformamide, N,N-diethylformamide, N,N-diisopropylformamide, N,N-dibutylformamide, N,N-dimethylacetamide, N,N-diethylacetamide, N,N-diisopropylacetamide, N,N-dimethylpropionamide, N,N-diethylpropionamide, N,N,2-trimethylpropionamide, acetamide, propionamide, isobutyramide, trimethylacetamide, nipecotamide, N,N-diethylnipecotamide, 1-formylpiperidine, and mixtures thereof.

Suitable amine solvents include: diethylamine, triethylamine, n-propyamine, isopropylamine, di-n-propylamine, diisopropylamine, n-butylamine, di-n-butylamine, tri-n-butylamine, isobutylamine, diisobutylamine, sec-butylamine, n-amylamine, sec-amylamine, diamylamine, triamylamine, n-hexylamine, sec-hexylamine, 2-ethylbutylamine, n-heptylamine, n-octylamine, 2-ethylhexylamine, di-2-ethylhexylamine, 3-methoxypropylamine, 2-methylbutylamine, isoamylamine, 1,2-dimethylpropylamine, hydrazine, ethylenediamine, 1,3-diaminopropane, 1,2-diaminopropane, 1,2-diamino-2-methylpropane, 1,3-diaminopentane, 1,1-dimethylhydrazine, N-ethylmethylamine, N-methylpropylamine, mono-n-butyl-diamylamine, N-methylethylenediamine, N-ethylethylenediamine, N-propylethylenediamine, N-isopropylethylenediamine, N,N′-dimethylethylenediamine, N,N-dimethylethylenediamine, N,N′-diethylethylenediamine, N,N-diethylethylenediamine, N,N-thisopropylethylenediamine, N,N-dibutylethylenediamine, N,N,N′-trimethylethylenediamine, 3-dimethylaminopropylamine, 3-diethylaminopropylamine, diethylenetriamine, tetraethylenepentamine, oyolohexylamine, dicyclohexylamine, 2-methoxyethylamine, bis(2-methoxyethyl)amine, 2-ethoxyethylamine, bis(2-ethoxyethyl)amine, 1-methoxyisopropylamine, aminoacetaldehyde diethyl acetal, methylaminoacetaldehyde dimethyl acetal, N,N-dimethylacetamide dimethyl acetal, dimethylaminoacetaldehyde diethyl acetal, diethylaminoacetaldehyde diethyl acetal, 4-aminobutyraldehyde diethyl acetal, 2-methylaminomethyl-1,3-dioxolane, ethanolamine, 3-amino-1-propanol, 2-hydroxyethylhydrazine, N,N-diethylhydroxylamine, 4-amino-1-butanol, 2-amino-1-butanol, 2-amino-2-methyl-1-propanol, 2-amino-2-methyl-1,3-propanediol, 2-amino-2-ethyl-1,3-propanediol, tris(hydroxymethyl)aminomethane, 2-(2-aminoethoxy)ethanol, 2-(methylamino)ethanol, 2-(ethylamino)ethanol, 2-(propylamino)ethanol, diethanolamine, triethanolamine, diisopropanolamine, triisopropanolamine, N,N-dimethylethanolamine, N,N-diethylethanolamine, 2-(dibutylamino)ethanol, 3-dimethylamino-1-propanol, 3-diethylamino-1-propanol, 1-dimethylamino-2-propanol, 1-diethylamino-2-propanol, N-methyldiethanolamine, N-ethyldiethanolamine, 3-amino-1,2-propanediol, piperazine, aminoethylpiperazine, 2-aminoethylethanolamine, 1-diethylamino-2,3-propanediol, 2-diethylamino-2-methyl-1-propanol, N-ethyl ethanolamine, N-butyl ethanolamine, N-ethyl diethanolamine, N-butyl diethanolamine, triethanolammonium hydroxide, aniline, dimethylaniline, diethylaniline, diethylbenzylamine, ethylene imine, propylene imine, piperazine, 1,2,4-trimethylpiperizine, morpholine, N-ethylmorpholine, N-phenylmorpholine, and mixtures thereof.

Suitable pyrrolidinone solvents include: 2-pyrrolidinone, N-methyl-2-pyrrolidinone, N-ethyl-2-pyrrolidinone, N-cyclohexyl-2-pyrrolidinone, N-(2-hydroxyethyl)pyrrolidinone, 5-methyl-2-pyrrolidinone, 3-methyl-2-pyrrolidinone, 2-pyrrolidinone, 1,5-dimethyl-2-pyrrolidinone, 1-ethyl-2-pyrrolidinone, 1-(2-hydroxyethyl)-2-pyrrolidinone, 5-methoxy-2-pyrrolidinone, 1-(3-aminopropyl)-2-pyrrolidinone, and mixtures thereof.

Suitable ether solvents include diethyl ether, diisopropyl ether, dibutyl ether, diamyl ether, dihexyl ether, tetrahydrofuran, dimethoxymethane, dioxane, trioxane, vinyl isopropyl ether, vinyl isobutyl ether, vinyl butyl ether, vinyl 2-ethylhexyl ether, methyl phenyl ether, n-butyl phenyl ether, amyl phenyl ether, amyl tolyl ether, amyl xylyl ether, diphenyl ether, furan, 2-methylfuran, 2,3-dihydropyran, tetrahydropyran, terpinyl methyl ether, 1,3-dioxolane, ethylene glycol dimethyl ether, ethylene glycol diethyl ether, diethylene glycol dimethyl ether, dipropylene glycol dimethyl ether, diethylene glycol diethyl ether, triethylene glycol dimethyl ether, diethylene glycol dibutyl ether, tetraethylene glycol dimethyl ether, poly(ethylene glycol) dimethyl ether, higlyme (methyl ether of >C9 alcohol ethoxylated with >five moles of ethylene oxide, CAS #366009-01-0), and mixtures thereof.

Suitable alcohol solvents include: methoxyethoxyethanol, methanol, ethanol, isopropanol, 1-propanol, 1-butanol, isobutanol, sec-butanol, t-butanol, 2-pentanol, 2-methyl-1-butanol, 3-methyl-1-butanol, 2-hexanol, 4-methyl-2-pentanol, 2-ethyl-1-butanol, 1-heptanol, 2-heptanol, 3-heptanol, 2-octanol, 2-ethyl-1-hexanol, 2-octanol, sec-octanol, 2-nonanol, 3,5,5-trimethyl-1-hexanol, 1-decanol, 2-decanol, isodecanol, 2-dodecanol, tridecanol, ethylene glycol, 1,3-propanediol, 2,3-butanediol, 1,5-pentanediol, 1,6-hexanediol, 1,7-heptanediol, 1,8-octanediol, cyclopentanol, cyclohexanol, cyclopentanemethanol, 3-cyclopentyl-1-propanol, 1-methylcyclopentanol, 3-methylcyclopentanol, 1,3-cyclopentanediol, 2-cyclohexylethanol, 1-cyclohexylethanol, 2,3-dimethylcyclohexanol, 1,3-cyclohexanediol, 1,4-cyclohexanediol, cycloheptanol, cyclooctanol, 1,5-decalindiol, 2,2-dichloroethanol, 1,1,1-trifluoroethanol, 2,2,3,3-tetrafluoro-1-propanol, 2,2,3,3,4,4,5,5-octafluoro-1-pentanol, 2-methoxyethanol, 2-ethoxyethanol, 2-propoxyethanol, 2-butoxyethanol, ethylene glycol monahexyl ether, ethylene glycol ethyl hexyl ether, 2-isobutoxyethanol, diethylene glycol, diethylene glycol monomethyl ether, diethylene glycol monoethyl ether, diethylene glycol monopropyl ether, diethylene glycol monobutyl ether, diethylene glycol rnonoisobutyl ether, diethylene glycol rnonohexyl ether, triethylene glycol, triethylene glycol monomethyl ether, triethylene glycol monoethyl ether, ethylene glycol monophenyl ether, tetraethylene glycol, terpinyl ethylene glycol ether, 3-ethoxy-1-propanol, 1-methoxy-2-propanol, propyleneglycol propyl ether, dipropylene glycol monomethyl ether, tripropylene glycol monomethyl ether, 1-phenoxy-2-propanol, 3-methoxy-1-butanol, 3-methoxy-3-methyl-1-butanol, 1,2-ethanediol, 1,2-propanediol, 1,3-propanediol, 1,2-butanediol, 1,3-butanediol, 1,4-butanediol, 2,3-butanediol, 2-butene-1,4-diol, 1,5-pentanediol, 2,4-pentanediol, 2,2-dimethyl-1,3-propanediol, 1,6-hexanediol, 2,5-hexanediol, 2-methyl-2,4-pentanediol, pinacol, 2,2-diethyl-1,3-propanediol, 2-ethyl-1,3-hexanediol, 2,5-dimethyl-3-hexyne-2,5-diol, 1,4-cyclohexanedimethanol, 3-ethoxy-1,2-propanediol, di(ethyleneglycol) ethylether, diethylene glycol, 2,4-dimethylphenol, 4-hydroxy-4-methyl-2-pentanone, allyl alcohol, crotyl alcohol, phenol, benzyl alcohol, furfuryl alcohol, tetrahydrofurfuryl alcohol, alpha-terpineol, tetrahydropyran-2-methanol, polyethylene glycol, glyceryl alpha-monomethyl ether, glyceryl alpha,gamma-dimethyl ether, glyceryl alpha-mono-n-butylether, glyceryl alpha-mono-isoamyl ether, and mixtures thereof.

Suitable carbonates include: dimethyl carbonate, diethyl carbonate, ethyl methyl carbonate, ethylene carbonate, propylene carbonate, and mixtures thereof.

In addition to the fluid medium and the mixture of binary and/or ternary coated chalcogenide nanoparticles, the precursor ink can optionally further comprise additives, an elemental chalcogen, or mixtures thereof.

In some embodiments, the precursor ink further comprises one or more additives selected from the group consisting of dispersants, surfactants, polymers, binders, cross-linking agents, emulsifiers, anti-foaming agents, dryers, fillers, extenders, thickening agents, film conditioners, anti-oxidants, flow agents, leveling agents, ligands, capping agents, defoamers, plasticizers, thixotropic agents, viscosity modifiers, dopants, and corrosion inhibitors. In some embodiments, additives are selected from the group consisting of dopants, polymers, and surfactants. Typically, the additives comprise less than 20 wt %, or less than 10 wt %, or less than 5 wt %, or less than 2 wt %, or less than 1 wt % of the CZTS/Se or CIGS/Se precursor ink.

Suitable polymeric additives include vinylpyrrolidone-vinylacetate copolymers and (meth)acrylate copolymers, including PVP/VA E-535 (International Specialty Products) and Elvacite® 2028 binder and Elvacite® 2008 binder (Lucite International, Inc.). In some embodiments, polymers can function as binders or dispersants. Suitable binders include polymers and oligomers with linear, branched, comb/brush, star, hyperbranched or dendritic structures and those with decomposition temperatures below 200° C. Decomposable polymers and oligomers useful herein include homo- and co-polymers of polyethers; homo- and co-polymers of polylactides; homo- and co-polymers of polycarbonates including, for example, Novomer PPC (Novomer, Inc.); homo- and co-polymers of 3-hydroxybutyric acid; homo and co-polymers of rnethacrylates; and mixtures thereof. If present, the polymeric or oligomeric binder is less than 20 wt %, or less than 10 wt %, or less than 5 wt. %, or less than 2 wt %, or less than 1 wt % of the CZTS/Se or CIGS/Se precursor ink.

Suitable surfactants include siloxy-, fluoryl-, alkyl-, alkynyl-, and ammonium-substituted surfactants. Selection is typically based on observed coating and dispersion quality and the desired adhesion to the substrate. Suitable surfactants include Byk® surfactants (Byk Chemie), Zonyl® surfactants (DuPont), Triton® surfactants (Dow), Surlynal® surfactants (Air Products), Dynol® surfactants (Air Products), and Tego® surfactants (Evonik Industries AG). In certain embodiments, surfactants can function as coating aids, capping agents, or dispersants. A suitable low-boiling surfactant is Surfynol® 61 surfactant from Air Products. Cleavable surfactants useful herein as capping agents include Diels-Alder adducts, thiirane oxides, sulfones, acetals, ketals, carbonates, and ortho esters. Cleavable surfactants include: alkyl-substituted Diels Alder adducts, Diels Alder adducts of furans; thiirane oxide; alkyl thiirane oxides; aryl thiirane oxides; piperylene sulfone, butadiene sulfone, isoprene sulfone, 2,5-dihydro-3-thiophene carboxylic acid-1,1-dioxide-alkyl esters, alkyl acetals, alkyl ketals, alkyl 1,3-dioxolanes, alkyl 1,3-dioxanes, hydroxyl acetals, alkyl glucosides, ether acetals, polyoxyethylene acetals, alkyl carbonates, ether carbonates, polyoxyethylene carbonates, ortho esters of formates, alkyl ortho esters, ether ortho esters, and polyoxyethylene ortho esters.

The CZTS/Se or CIGS/Se precursor ink can also optionally comprise sodium salts and elemental chalcogens. In embodiments where sodium salts and/or elemental chalcogens are added to the CZTS/Se or CIGS/Se precursor ink, the ink is said to be “doped” with these additives. If present, the chalcogen is typically between 0.1 wt % and 10 wt % of the CZTS/Se or CIGS/Se precursor ink. Suitable dopants include sodium and alkali-containing compounds selected from the group consisting of: alkali compounds comprising N-, O-, C-, S-, or Se-based organic ligands, alkali sulfides, alkali selenides, and mixtures thereof. In other embodiments, the dopant comprises an alkali-containing compound selected from the group consisting of: alkali-compounds comprising amidos; alkoxides; acetylacetonates; carboxylates; hydrocarbyls; O-, N-, S-, Se-, halogen-, or tri(hydrocarbyl)silyl-substituted hydrocarbyls; thio- and selenolates; thio-, seleno-, and dithiocarboxylates; dithio-, diseleno-, and thioselenocarbamates; and dithioxanthogenates. Other suitable dopants include antimony chalcogenides selected from the group consisting of: antimony sulfide and antimony selenide.

In some embodiments, the precursor ink comprises an elemental chalcogen selected from the group consisting of sulfur, selenium, and mixtures thereof. Useful forms of sulfur and selenium powders can be obtained from Sigma-Aldrich (St. Louis, Mo.) and Alfa Aesar (Ward Hill, Mass.). In some embodiments, the chalcogen powder is soluble in the fluid medium. If the chalcogen is not soluble in the fluid medium, its particle size can be 1 nm to 200 microns. In some embodiments, the particles have an average longest dimension of less than about 100 microns, 50 microns, 25 microns, 10 microns, 5 microns, 4 microns, 3 microns, 2 microns, 1.5 microns, 1.25 microns, 1.0 micron, 0.75 micron, 0.5 micron, 0.25 micron, or 0.1 micron. In some embodiments, the chalcogen particles are smaller than the thickness of the film that is to be formed. The chalcogen particles can be formed by ball milling, evaporation-condensation, melting and spraying (“atomization”) to form droplets, or emulsification to form colloids.

Another aspect of the invention is a process comprising disposing a CZTS/Se precursor ink onto a substrate to form a coated substrate, wherein the ink comprises:

a) a fluid medium;
b) chalcogenide-capped copper-containing chalcogenide nanoparticles;
c) chalcogenide-capped tin-containing chalcogenide nanoparticles; and
d) chalcogenide-capped zinc-containing chalcogenide nanoparticles,
wherein:
the molar ratio of total chalcogen to (Cu+Zn+Sn) of the ink is at least about 1; and the molar ratio of Cu:Zn:Sn is about 2:1:1.

Another aspect of the invention is a process comprising disposing a CIGS/Se precursor ink onto a substrate to form a coated substrate, wherein the ink comprises:

a) a fluid medium;
b) chalcogenide-capped copper-containing chalcogenide nanoparticles;
c) chalcogenide-capped indium-containing chalcogenide nanoparticles;
and, optionally,
d) chalcogenide-capped gallium-containing chalcogenide nanoparticles,
wherein:
the molar ratio of total chalcogen to (Cu+In+Ga) of the ink is at least about 1; and
the molar ratio of Cu:(In+Ga) is about 1:1.

Another aspect of the invention provides a coated substrate comprising:

a) a substrate; and
b) at least one layer disposed on the substrate comprising:

i) chalcogenide-capped copper-containing chalcogenide nanoparticles;

ii) chalcogenide-capped tin-containing chalcogenide nanoparticles; and

iii) chalcogenide-capped zinc-containing chalcogenide nanoparticles;

wherein:

the molar ratio of total chalcogen to (Cu+Zn+Sn) is at least about 1; and

the molar ratio of Cu:Zn:Sn is about 2:1:1.

Another aspect of the invention provides a coated substrate comprising:

a) a substrate; and
b) at least one layer disposed on the substrate comprising:

i) chalcogenide-capped copper-containing chalcogenide nanoparticles;

ii) chalcogenide-capped indium-containing chalcogenide nanoparticles; and, optionally,

iii) chalcogenide-capped gallium-containing chalcogenide nanoparticles,

wherein:

the molar ratio of total chalcogen to (Cu+In+Ga) is at least about 1; and

the molar ratio of Cu:(In+Ga) is about 1:1.

In some embodiments, the amount of Cu, Zn, and Sn can deviate from a 2:1:1 molar ratio by +/−40 mol %, +/−30 mole %, +/−20 mole %, +/−10 mole %, or +/−5 mole %. Hence, the molar ratio of Cu:Zn:Sn of the CZTS/Se precursor ink can be, for example, 1.75:1:1.35 or 1.78:1:1.26 or other non-integer ratios. In some embodiments, the molar ratio of Cu to (Zn+Sn) is less than one. In some embodiments, the molar ratio of Zn to Sn is greater than one.

In some embodiments, the molar ratio of Cu:(In+Ga) can deviate from a 1:1 molar ratio by +/−mole %, +/−20 mole %, +/−10 mole %, or +/−5 mole %. Hence, the molar ratio of Cu:(In+Ga) of the CIGS/Se precursor ink can be, for example, 0.85:1.15 or other non-integer ratios. In some embodiments, the molar ratio of Cu:(In+Ga) is less than 1.

As defined herein, sources for the total chalcogen include the metal chalcogenides (e.g., the chalcogenide-capped Cu-, Zn- or Sn-containing chalcogenide nanoparticles in the case of CZTS/Se and the chalcogenide-capped Cu-, In-, or Ga-containing chalcogenide nanoparticles in the case of CIGS/Se) and the optional elemental chalcogen compound. As defined herein, the moles of total chalcogen are determined by multiplying the moles of each metal chalcogenide by the number of equivalents of chalcogen that it contains and then summing these quantities together with the number of moles of any optional elemental chalcogen compound present in the ink. Although moles of sulfur- and selenium-based capping agents and fluid media present can contribute to the amount of total chalcogenide, they are not included in this calculation. For example, the moles of (Cu+Zn+Sn) are determined by multiplying the moles of each Cu- or Zn- or Sn-containing species by the number of equivalents of Cu or Zn or Sn that it contains and then summing these quantities. As an example, the molar ratio of total chalcogen to (Cu+Zn+Sn) for an ink comprising sulfur, Cu₂S particles, ZnS particles, and SnS₂ particles=[(moles of S)+(moles of Cu₂S)°(moles of ZnS)+2(moles of SnS₂)]/[2(moles of Cu₂S) +(moles of ZnS)°(moles of SnS₂)].

The precursor ink is deposited on a surface of a substrate by any of several conventional coating or printing techniques, e.g., spin-coating, doctor blade coating, spraying, dip-coating, rod-coating, drop-cast coating, wet coating, roller coating, slot-die coating, meyerbar coating, capillary coating, ink-jet printing, draw-down coating, ink-jet printing, contact printing, gravure printing, flexographic printing, and screen printing. The coating can be dried by evaporation, by applying vacuum, by beating, or by combinations thereof. In some embodiments, the substrate and disposed ink are heated at a temperature from 80-400° C. 80-350° C., 100-300° C., 175-400° C., 200-400° C., 250-400° C., 300-400° C., 120-250° C., or 150-190° C. to remove at least a portion of the solvent, if present, by-products, and volatile capping agents. In some embodiments, the drying step is carried out under an inert atmosphere. In some embodiments, the drying step is carried out under an atmosphere comprising oxygen. The drying step can be a separate, distinct step, or can occur as the substrate and precursor ink are heated in an annealing step.

The substrate can be rigid or flexible. In one embodiment, the substrate comprises: (i) a base; and (ii) optionally, an electrically conductive coating on the base. The base material is selected from the group consisting of glass, metals, ceramics, and polymeric films. Suitable base materials include metal foils, plastics, polymers, metalized plastics, glass, solar glass, low-iron glass, green glass, soda-lime glass, metalized glass, steel, stainless steel, aluminum, ceramics, metal plates, metalized ceramic plates, and metalized polymer plates. In some embodiments, the base material comprises a filled polymer (e.g., a polyimide and an inorganic filler). In some embodiments, the base material comprises a metal (e.g., stainless steel) coated with a thin insulating layer (e.g., alumina).

Suitable electrically conductive coatings include metal conductors, transparent conducting oxides, and organic conductors. Of particular interest are substrates of molybdenum-coated soda-lime glass, molybdenum-coated polyimide films, and molybdenum-coated polyimide films further comprising a thin layer (e.g., less than 100 angstroms in thickness) of a sodium compound (e.g., NaF, Na₂S, or Na₂Se).

In some embodiments, the molar ratio of Cu:Zn:Sn in the coating on the substrate is about is 2:1:1. In other embodiments, the molar ratio of Cu to (Zn+Sn) is less than one. In other embodiments, the molar ratio of Zn:Sn is greater than one. In some embodiments, the molar ratio of Cu:(In+Ga) in the coating on the substrate is about 1:1. In other embodiments, the molar ratio of Cu to (In+Ga) is less than one.

In some embodiments, the coated substrate is heated at about 100-800° C., 200-800° C., 250-800° C., 300-800° C., 350-800° C., 400-800° C., 400-650° C., 450-600° C., 450-550° C., 450-525° C., 100-700° C., 200-650° C., 300-600° C., 350-575° C., or 350-525° C. In some embodiments, the coated substrate is heated for a time in the range of about 1 min to about 48 h; 1 min to about 30 min; 10 min to about 10 h; 15 min to about 5 h; 20 min to about 3 h; or, 30 min to about 2 h. Typically, the annealing comprises thermal processing, rapid thermal processing (RTP), rapid thermal annealing (RTA), pulsed thermal processing (PTP), laser beam exposure, beating via IR lamps, electron beam exposure, pulsed electron beam processing, beating via microwave irradiation, or combinations thereof. Herein, RTP refers to a technology that can be used in place of standard furnaces and involves single-wafer processing, and fast beating and cooling rates. RTA is a subset of RTP, and consists of unique beat treatments for different effects, including activation of dopants, changing substrate interfaces, densifying and changing states of films, repairing damage, and moving dopants. Rapid thermal anneals are performed using either lamp-based beating, a hot chuck, or a hot plate. PTP involves thermally annealing structures at extremely high power densities for periods of very short duration, resulting, for example, in defect reduction. Similarly, pulsed electron beam processing uses a pulsed high energy electron beam with short pulse duration. Pulsed processing is useful for processing thin films on temperature-sensitive substrates. The duration of the pulse is so short that little energy is transferred to the substrate, leaving it undamaged.

In some embodiments, the annealing is carried out under an atmosphere comprising: an inert gas (nitrogen or a Group VIIIA gas, particularly argon); optionally hydrogen; optionally, a chalcogen source such as selenium vapor, sulfur vapor, hydrogen sulfide, hydrogen selenide, diethyl selenide, or mixtures thereof; and, in the case of CZTS/Se films, optionally, a tin source. Suitable sources of tin include elemental tin, including tin powder, tin particles, and molten tin; and tin chalcogenides, including SnS₂, SnSe₂, Sn(S/Se)₂, SnS, SnSe, and Sn(S/Se). In some embodiments, at least a portion of the chalcogen present in the coating (e.g., S) can be exchanged (e.g., S can be replaced by Se) by conducting the annealing step in the presence of a different chalcogen (e.g., Se). In some embodiments, annealings are conducted under a combination of atmospheres. For example, a first annealing is carried out under an inert atmosphere and a second annealing is carried out in an atmosphere comprising an inert gas and a chalcogen source as described above, or vice versa. In some embodiments, the annealing is conducted with slow beating and/or cooling steps, e.g., temperature ramps and declines of less than about 15° C. per min, 10° C. per min, 5° C. per min, 220° C. per min, or 120° C. per min. In other embodiments, the annealing is conducted with rapid and/or cooling steps, e.g., temperature ramps and declines of greater than about 15° C. per min, 20° C. per min, 30° C. per min, 45° C. per min, or 60° C. per min.

By varying the ink concentration and/or coating technique and temperature, layers of varying thickness can be coated in a single coating step. In some embodiments, the coating thickness can be increased by repeating the coating and drying steps. These multiple coatings can be conducted with the same ink or with different inks. As described above, wherein two or more inks are mixed, the coating of multiple layers with different inks can be used to fine-tune stoichiometry and purity of the CZTS/Se or CIGS/Se films by fine-tuning metal ratios. Soft-bake and annealing steps can be carried out between the coating of multiple layers. In these instances, the coating of multiple layers with different inks can be used to create gradient layers, such as layers that vary in the S/Se ratio.

The annealed film typically has an increased density and/or reduced thickness versus that of the wet precursor layer. In some embodiments, the film thicknesses of the dried and annealed coatings are 0.1-200 microns; 0.1-100 microns; 0.1-50 microns; 0.1-25 microns; 0.1-10 microns; 0.1-5 microns; 0.1-3 microns; 0.3 3 microns; or 0.5-2 microns.

Application of multiple coatings or washing the coating can serve to reduce carbon-based impurities in the coatings and films. For example, after an initial coating, the coated substrate can be dried and then a second coating can be applied and coated by spin-coating. The spin-coating step can wash organics out of the first coating. Alternatively, the coated film can be soaked in a solvent and then spun-coated to wash out the organics. Examples of useful solvents for removing organics in the coatings include alcohols, e.g., methanol or ethanol, and hydrocarbons, e.g., toluene. As another example, dip-coating of the substrate into the ink can be alternated with dip-coating of the coated substrate into a solvent bath to remove impurities and capping agents. Alternatively, binary sulfides and other impurities can be removed by etching the annealed film using techniques such as those used for CIGS/Se films.

Another aspect of this invention is a process for preparing a photovoltaic cell comprising a film comprising CZTS/Se or CIGS/Se. The photovoltaic cell can be a single-junction cell or in tandem with other cells. Various embodiments of the film are the same as described above. In some embodiments, the film is the absorber layer of a photovoltaic cell.

Various electrical elements can be formed, at least in part, by the use of the chalcogenide-capped nanoparticle precursors to CZTS/Se and CIGS/Se and processes described herein. One aspect of this invention provides a process for making an electronic device and comprises depositing one or more layers in layered sequence onto the annealed film of the substrate. The layers can be selected from the group consisting of conductors, semiconductors, and insulators.

Another aspect of this invention provides a process for manufacturing thin-film photovoltaic cells comprising CZTS/Se or CIGS/Se. A typical photovoltaic cell includes a substrate, a back contact layer (e.g., molybdenum), an absorber layer (also referred to as the first semiconductor layer), a buffer layer (also referred to as the second semiconductor layer), and a top contact layer. The photovoltaic cell can also include an electrode pad on the top contact layer, and an anti-reflective (AR) coating on the front (light-facing) surface of the substrate to enhance the transmission of light into the semiconductor layer. The buffer layer, top contact layer, electrode pads and antireflective layer can be deposited onto the annealed CZTS/Se or CIGS/Se film in layered sequence.

In one embodiment, the process provides a photovoltaic device and comprises depositing the following layers in layered sequence onto the annealed coating of the substrate having an electrically conductive layer present: (i) a buffer layer; (ii) a transparent top contact layer, and (iii) optionally, an antireflective layer. In yet another embodiment, the process provides a photovoltaic device and comprises disposing one or more layers selected from the group consisting of buffer layers, top contact layers, electrode pads, and antireflective layers onto the annealed CZTS/Se or CIGS/Se film. In some embodiments, construction and materials for these layers are analogous to those of known CIGS/Se photovoltaic cells. Suitable substrate materials for the photovoltaic cell substrate are as described above.

### EXAMPLES

### General

All metal salts and reagents were obtained from commercial sources, and used as received, unless otherwise noted. Whatman® Puradisc™ 25 GD 1.0 μm GMF-150 filter media with polypropylene housing were used for filtration of nanoparticle dispersions.

Annealings were carried out in an argon atmosphere comprising selenium. Annealings were carried out in a single-zone Lindberg/Blue (Ashville, N.C.) tube furnace equipped with an external temperature controller and a two-inch quartz tube. The coated substrates were placed inside of a graphite box (Industrial Graphite Sales, Harvard, Ill.) with a lid with a center hole of 1 mm in diameter. The box dimensions were 5″ length×1.4″ width×0.625″ height with a wall and lid thickness of 0.125″. The selenium was either placed in small ceramic boats within the graphite box or directly on the floor of the graphite box. Vacuum was applied to the tube for 10-15 min, followed by an argon purge for 10-15 min. This process was carried out three times. A gas inlet and outlet were located at opposite ends of the tube, and the tube was purged with the inert gas while beating and cooling.

Mo-sputtered SLG substrates were purchased from Thin Film Devices, Inc. (Anaheim, Calif.) with a 750 nm layer of Mo on Pilkington Optifloat™ Clear 3.2 mm glass (Pilkington North America, Inc., Toledo, Ohio).

Powder X-ray diffraction was used for the identification of crystalline phases. Data were obtained with a Philips XPERT automated powder diffractorneter, Model 3040. The diffractometer was equipped with automatic variable anti-scatter and divergence slits, X'Celerator RTMS detector, and Ni filter. The radiation was CuK(alpha) (45 kV, 40 mA). Data were collected at room temperature from 4 to 120°. 2-theta, using a continuous scan with an equivalent step size of 0.02°, and a count time of from 80-240 sec per step in theta-theta geometry. Thin film samples were presented to the X-ray beam as made. MDI/Jade software version 9.1 was used with the International Committee for Diffraction Data database PDF4+ 2008 for phase identification and data analysis.

### Example 1

### CuS Nanoparticle Synthesis

Cu(II) acetylacetonate (1.047 g) was dissolved in 80 mL of chloroform. Ammonium sulfide (1.6 mL of a 40-48 wt. % solution in water) was added to 160 mL of water, and the resulting solution was added to the chloroform solution. The two-phase mixture was shaken for 2 min. The aqueous phase, which turned from transparent pale yellow to dark brown after shaking, was separated and mixed with 160 mL of acetonitrile to flocculate the resulting nanoparticles. The nanoparticles were then isolated by centrifuging and discarding the supernatant. According to TEM, the nanoparticles were nanodiscs of about 100 nm diameter and 10 to 20 nm thickness. Zeta-potential of the CuS nanoparticles in water was about −40 mV, which was consistent with negatively charged ions, such as S²⁻ ions, on the nanoparticle surface. Tof-SIMS and ESCA analysis indicated some copper sulfate impurities in this sample. According to FTIR, TEM, and Tof-SIMS analysis, there were only trace organic impurities in this sample.

### Example 2

### ZnS Nanoparticle Synthesis

The procedure of Example 1 was followed using 12 g of zinc acetylacetonate hydrate, 20 mL of chloroform, 4 mL of the ammonium sulfide solution, 50 mL of water, and 50 mL of acetonitrile. The pellet of nanoparticles was further purified by washing with 60 mL of methanol, followed by another wash with 30 mL of methanol. According to TEM, the resulting nanoparticles were close to spherical in shape and 1 to 5 nm in diameter. Zeta-potential of the ZnS nanoparticles in water was about −28 mV, which was consistent with negatively charged ions, such as S²⁻ ions, on the nanoparticle surface. FTIR, TEM, and Tof-SIMS analysis indicated the presence of organic impurities in this sample.

### Example 3

### ZnS Nanoparticle Synthesis

The procedure of Example 2 was followed using 0.6 g of zinc acetylacetonate hydrate, 40 mL of chloroform, 2 mL of the ammonium sulfide solution, 50 mL of water, and 50 mL of acetonitrile. After shaking and subsequent phase separation, the aqueous phase was isolated and extracted with chloroform (2×50 mL). According to TEM and FIR, the ZnS nanoparticles obtained contained only traces of organic impurities.

### Example 4

### SnS Nanoparticle Synthesis

The procedure of Example 1 was followed using 1.62 g of tin(II) 2-ethylhexanoate, 20 mL of chloroform, 4 mL of the ammonium sulfide solution, 50 mL of water, and 50 mL of acetonitrile. The pellet of nanoparticles was further purified by washing with 20 mL of methanol. According to TEM, the resulting nanoparticles were close to spherical in shape and 5 to 10 nm in diameter. Zeta-potential of the SDS nanoparticles in water was about 47 mV, which is consistent with negatively charged ions, such as S³⁻ ions, on the nanoparticle surface. FTIR, TEM, and Tof-SIMS analysis indicated the presence of organic impurities in this sample.

### Example 5

### Cu₂SnS₃ Nanoparticle Synthesis

Cu(II) acetylacetonate (698 mg) and tin(II) 2-ethylhexanoate (540 mg) were dissolved in 80 mL of chloroform. Ammonium sulfide (1.6 mL of a 40-48 wt. % solution in water) was added to 160 mL of water, and the resulting solution was added to the chloroform solution. The two-phase mixture was shaken for 2 min. The aqueous phase, which turned from transparent pale yellow to dark brown after shaking, was separated and mixed with 160 mL of acetonitrile to flocculate the resulting nanoparticles. The nanoparticles were then isolated by centrifuging and discarding the supernatant. According to TEM, the product contains copper tin sulfide nanocrystals with diameters ranging from 5 to 30 nm. There are also copper sulfide nanodiscs of 100 to 500 nm in diameter in this sample. XAS indicated that 33% of the copper exists as Cu₂SnS₃, 36% as Cu₂S, 23% as CuS, and 8% as CuO. XAS data also indicated that 25% of the Sn exists as Cu₂SnS₃, with the remainder as SnO₂.

### Example 6

### Preparation of a CZTS Precursor Ink

The nanoparticles obtained in Examples 1, 2 and 4 were used to formulate inks. Approximately 227 mg of CuS nanoparticles, 198 mg of ZnS nanoparticles, and 215 mg of SnS nanoparticles were each dispersed in 1 mL of deionized water. The three dispersions were sonicated in a bath sonicator for 20 min. Then 846 microliters of the CuS dispersion, 490 microliters of the ZnS dispersion, and 698 microliters of the SnS dispersion were mixed. The resulting CZTS precursor ink was further sonicated for 15 min.

### Example 7

### Preparation of a Coated Substrate

A portion of the CZTS precursor ink of Example 6 was deposited and spin-coated onto a molybdenum-coated glass substrate with a three-step spinning procedure involving ramp rates of 1000 rpm: (1) spin at 1000 rpm for 15 sec, (2) then spin at 1500 rpm for 20 sec, and (3) finally, spin at 3000 rpm for 5 sec. The deposition and spin coating procedures were repeated 7 times to yield an 8-layer coating. After spin-coating each layer, the sample was soft-baked in the air on a hot plate at 200° C. for 2 min.

### Example 8

### Formation of a CZTSe Film

A substrate coated with a CZTS precursor layer was prepared as described in Example 7. The coated substrate was placed in a graphite box containing 150 mg of elemental selenium in a small ceramic boat and heated at 560° C. for 20 min. XRD of the article indicated the presence of CZTSe, Mo, and MoSe₂. SEM showed that the CZTSe film had grains of ˜200 to 300 nm in size.

### Example 9

### In₂S₃ Nanoparticle Synthesis

Indium 2-ethylhexanoate (2.178 g) is dissolved in 20 mL of chloroform. Ammonium sulfide (4 mL of a 40-48 wt % solution in water) is added to 50 mL of water, and the resulting solution is added to the chloroform solution. The two-phase mixture is shaken for 2 min. The aqueous phase is isolated and extracted twice with 50 mL chloroform. Then 150 mL acetonitrile is added to the aqueous phase to flocculate the nanoparticles. The nanoparticles are isolated by centrifuging and discarding the supernatant.

### Example 10

### Ga₂S Nanoparticle Synthesis

The procedure in Example 9 is carried out by using gallium 2-ethylhexanoate (1.997 g) instead of indium 2-ethylhexanoate.

### Example 11

### Preparation of a CIGS Precursor Ink

The nanoparticles obtained in Examples 1, 9, and 10 are used to formulate inks. Approximately 211 mg of CuS nanoparticles, 297 mg of In₂S₃ nanoparticles, and 92 mg of Ga₂S₃ nanoparticles are mixed and dispersed in 1 mL of formamide. The resulting CIGS precursor ink is further sonicated for 15 min.

### Example 12

### Preparation of a Coated Substrate

A portion of the CIGS precursor ink of Example 11 is deposited and spin-coated onto a molybdenum-coated glass substrate with a three-step spinning procedure: (1) 1000 rpm for 15 sec, (2) 1500 rpm for 20 sec, and (3) 3000 rpm for 5 sec. After spin-coating, the sample is soft-baked in the air on a hot plate at 200° C. for 2 min.

### Example 13

### Formation of a CIGS/Se Film

A substrate coated with a CIGS precursor layer is prepared as described in Example 12. The coated substrate is placed in a graphite box containing 150 mg of elemental selenium in a small ceramic boat and heated at 560° C. for 20 min.

### Example 14

### Preparation of a CZTS Precursor Ink

SnS₂ (1.83 g) and 5 mL of an ammonium sulfide solution (40-48 wt % in water) are mixed with 50 mL water and stirred overnight. Acetone (150 mL) is added to form a yellow precipitate, which is dried in air for about 2 h. The solid is dissolved in a mixture of formamide (50 mL) and ammonium sulfide solution (1.5 mL). The resulting formamide solution (5 mL) is added to CuS nanoparticles (192 mg) from Example 1 and ZnS nanoparticles (97 mg) from Example 3. A CZTS precursor ink is formed after sonicating to disperse the nanoparticles.

What is claimed is:

1. A CZTS/Se precursor ink comprising:
a) a fluid medium;
chalcogenide-capped copper-containing chalcogenide nanoparticles;
c) chalcogenide-capped tin-containing chalcogenide nanoparticles; and
d) chalcogenide-capped zinc-containing chalcogenide nanoparticles,
wherein:
the molar ratio of total chalcogen to (Cu+Zn+Sn) of the ink is at least about is 1, and the molar ratio of Cu:Zn:Sn is about 2:1:1.

2. A process comprising disposing the CZTS/Se precursor ink of claim 1 onto a substrate to Form a coated substrate.

3. The process of claim 2, further comprising beating the coated substrate to form a CZTS/Se film on the substrate.

4. A coated substrate formed according to the process of claim 2 or 3.

5. A CIGS/Se precursor ink comprising:
a) a fluid medium;
b) chalcogenide-capped copper-containing chalcogenide nanoparticles;
c) chalcogenide-capped indium-containing chalcogenide nanoparticles; and, optionally,
d) chalcogenide-capped gallium-containing chalcogenide nanoparticles,
wherein:
the molar ratio of total chalcogen to (Cu+In+Ga) of the ink is at least about 1, and the molar ratio of Cu:(In+Ga) is about 1:1.

6. A process comprising disposing the CIGS/Se precursor ink of claim 5 onto a substrate to form a coated substrate.

7. The process of claim 6, further comprising beating the coated substrate to form a CIGS/Se film on the substrate.

8. A coated substrate formed according to the process of claim 6 or 7.

9. A process comprising;
a) providing a first composition comprising a first solvent and one or more metal complexes, and a second composition comprising a second solvent and a chalcogenide compound selected from the group consisting of sulfides, selenides, and tellurides, wherein the first and second solvents are immiscible;
b) combining the first and second compositions to form a third composition;
c) agitating the third composition;
d) phase-separating the third composition to form a first phase comprising the first solvent and a second phase comprising the second solvent; and
e) isolating the second phase.

10. The process of claim 9, further comprising;
f) adding a third solvent to the isolated second phase to form a precipitate; and
g) isolating the precipitate.

11. The process of claim 9 wherein the one or more metal complexes comprise metals selected from the group consisting of copper, zinc, tin, gallium and indium.

12. The process of claim 10 wherein the precipitate in step g) comprises chalcogenide-capped metal-containing chalcogenide nanoparticles.
